(19) United States
(12) Patent Application Publication
(10) Pub. No.: US 2003/0074629 A1
(43) Pub. Date: Apr. 17, 2003

(54) Data synchronization within a communication system

(76) Inventor: Jeffrey A. Levin, San Diego, CA (US)

Correspondence Address: Sarah Kirkpatrick, Manager, Intellectual Property Administration, QUALCOMM Incorporated, 5775 Morehouse Drive, San Diego, CA, 92121-1714, US

(21) Appl. No.: 09/976,079

(22) Filed: Oct. 11, 2001

(51) Int. Cl. H03M 13/00; H04L 7/00

(52) U.S. Cl. 714/800; 375/365

(57) ABSTRACT

An apparatus, such as a modem or other component within a spread spectrum communication system, is described that introduces one or more “entropy” bits into a data stream to ensure that other components of the communication system readily detect data frame misalignment. In particular, an entropy bit is introduced within each frame to help ensure that the other components generate parity errors when not properly synchronized with the framing of the data stream. The entropy bits have values that change relatively frequently, and are unrelated to the other data bits of the frames. The entropy bit may, for example, be randomly or pseudo-randomly generated.

### TECHNICAL FIELD

The invention relates generally to wireless communication systems and, more particularly, to distribution of digitized waveforms within such systems.

### BACKGROUND

A number of conventional wireless communication techniques have been developed. One common technique is code division multiple access (CDMA) in which multiple communications are simultaneously conducted over a radio-frequency (RF) spectrum. Example wireless communication devices (“subscriber units”) that have incorporated CDMA technology include cellular radiotelephones, PCMCIA cards incorporated within computers, personal digital assistants (PDAs) equipped with wireless communication capabilities, and the like.

A CDMA system may be designed to support one or more CDMA standards such as (1) the “TIA/EIA-95-B Mobile Station-Base Station Compatibility Standard for Dual-Mode Wideband Spread Spectrum Cellular System” (the IS-95 standard), (2) the “TIA/EIA-98-C Recommended Minimum Standard for Dual-Mode Wideband Spread Spectrum Cellular Mobile Station” (the IS-98 standard), (3) the standard offered by a consortium named “3rd Generation Partnership Project” (3GPP) and embodied in a set of documents including Document Nos. 3G TS 25.211, 3G TS 25.212, 3G TS 25.213, and 3G TS 25.214 (the WCDMA standard), (4) the standard offered by a consortium named “3rd Generation Partnership Project 2” (3GPP2) and embodied in a set of documents including “TR-45.5 Physical Layer Standard for cdma2000 Spread Spectrum Systems,” the “C.S0005-A Upper Layer (Layer 3) Signaling Standard for cdma2000 Spread Spectrum Systems,” and the “C.S0024 cdma2000 High Rate Packet Data Air Interface Specification” (the cdma2000 standard), and (5) some other standards. A system that implements the High Rate Packet Data specification of the cdma2000 standard is referred to herein as a high data rate (HDR) system. The HDR system is documented in TIA/EIA-IS-856, “CDMA2000 High Rate Packet Data Air Interface Specification”. Proposed wireless systems also provide a combination of HDR and low data rate services (such as voice and fax services) using a single air interface.

A typical CDMA communication system includes a number of mobile subscriber units that encode voice and data in CDMA waveforms. The subscriber units communicate with base stations, also referred to as base transceiver subsystems (BTS), cell stations, cell sites, or simply cells. A base station demodulates incoming CDMA waveforms received from subscriber units within a limited geographic region, and transmits outgoing CDMA waveforms to the subscriber units. A base station controller (BSC) provides an interface between the base stations and the public switched telephone network (PSTN) for routing the signals to other remote base stations or to any conventional telephony system. In general, transmission from the base station to the subscriber unit is referred to as the Forward CDMA Channel, and is sometimes called a downlink. Transmission from the subscriber unit to the base station is referred to as the Reverse CDMA Channel, and is sometimes called an uplink.

Base stations typically include a number of discrete components interconnected by cables, back planes, busses, printed-circuit traces and the like. A base station may include, for example, one or more transmit modulators that produce a serialized stream of data bits organized as frames, zero or more summation units to combine the output of the modulators into a resultant serialized stream of data bits. The base station typically also includes a transmit power amplifier and an antenna to output a spread-spectrum waveform based on the combined stream of data bits.

One challenge in such a system is to maintain synchronization between the various components of the base station. Each modulator must, for example, determine a starting bit for each frame within the stream of serialized data. One conventional approach is to use a separate synchronization signal between each modem and the transmitter to indicate the beginning of each frame within the data stream. However, these interconnections between the components of a base station add cost, consume space, and provide an opportunity for circuit breaks to occur. Moreover, a relatively large number of hard-wired interconnections can become bulky and cumbersome.

Another conventional approach to determine synchronization is for a component, such as the transmitter, to adjust frame alignment upon detecting some number of parity errors within the serialized data stream. The transmitter typically “slides” the frame by one bit upon detecting a substantial number of parity errors. The transmitter continues this process until settling in on the correct framing. This approach, however, may not converge to the correct framing depending upon the characteristics of the data. In particular, data representing degenerate waveforms, such as unfiltered CDMA signals or a waveform carrying substantially constant data, may cause the transmitter or other “downstream” components receiving the serial data stream to experience significant periods without detecting parity errors even when framing is misaligned.

### SUMMARY

In general, the invention is directed to a system using serialized data streams with one or more parity bits introduced to allow detection of framing misalignment when the data streams are received and de-serialized. In particular, one or more “entropy” bits are added to the serialized data stream in positions where the entropy bits can cause parity errors on misaligned frames, yet will not interfere with parity checks on correctly aligned frames. The entropy bits may, for example, be truly random or pseudo-randomly generated.

In one embodiment, the invention is directed to a method in which a data stream is generated having a data frame format that includes at least one bit to provide error detection and at least one entropy bit. The data stream may be generated by, for example, a modem within a CDMA base station. A waveform is transmitted based on the data stream.

In another embodiment, the invention is directed to an apparatus, such as a modem or other component within a CDMA base station. The apparatus comprises a modulator to produce spread spectrum data, and an output interface coupled to the modulator to generate an outbound data stream from the spread spectrum data. The output interface formats the data stream according to data frames. Each data frame includes a set of data bits, at least one bit representing error detection information calculated from the data bits, and an entropy bit. The output interface selectively includes the entropy bits based on a configurable setting.

The invention is capable of providing a number of advantages. By making use of an entropy bit the downstream components, such as a transmitter within a CDMA base station, more quickly correct for misaligned framing positions. Accordingly, the invention provides a more robust synchronization mechanism between components of a wireless communication system. Consequently, the invention can reduce a number of output pins for the components by eliminating the need for an independent synchronization signal to be produced in parallel with the serialized data stream. Advantageously, this may reduce the number of interconnects within, for example, a CDMA base station.

In addition, the entropy bit may be used to convey other useful information, such as a time stamp indication, as long as the values assumed while encoding the information exhibit random characteristics relative to the primary serialized data stream.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a block diagram illustrating a spread spectrum telecommunication system.

FIG. 2 is a block diagram of a portion of a base station for handling spread spectrum communication on a single channel.

FIG. 3 is a block diagram illustrating an example cell site modem within a base station.

FIG. 4 is a timing diagram illustrating an example format for a serialized data stream produced the cell site modem.

FIG. 5 is a timing diagram illustrating another example format for a serialized data stream produced by the modem.

FIG. 6 illustrates an exemplary bit pattern for a timing code.

FIG. 7 is a flow chart illustrating the use of one or more “entropy” bits within a spread spectrum communication system.

### DETAILED DESCRIPTION

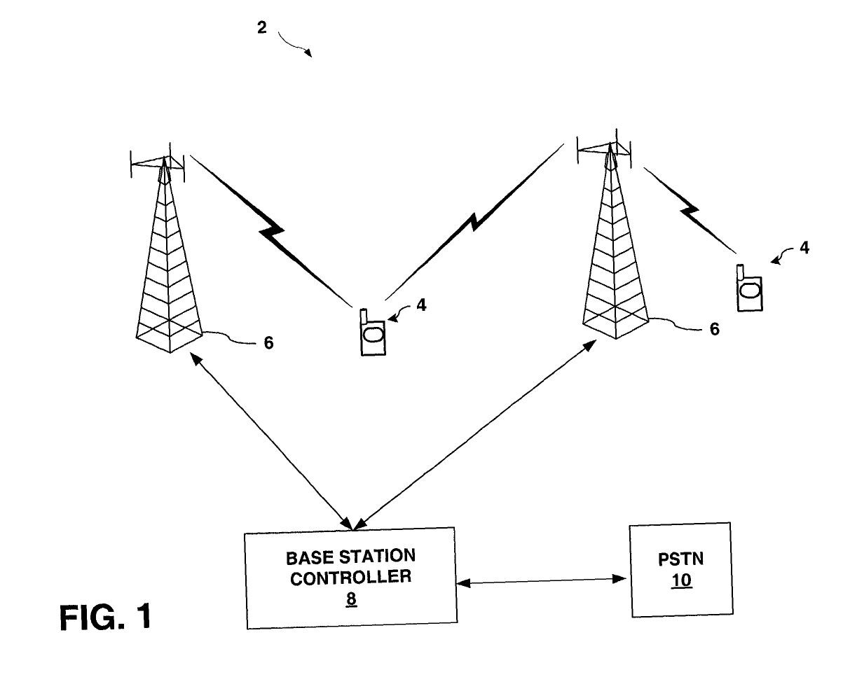

FIG. 1 is a block diagram illustrating a spread spectrum telecommunication system 2 in which subscriber units 4 communicate via base stations 6. Examples of subscriber units 4 include cellular radiotelephones, PCMCIA cards incorporated within computers, personal digital assistants (PDAs) equipped with wireless communication capabilities, and the like. Base station controller (BSC) 8 provides an interface between base stations 6 and the public switched telephone network (PSTN) 10. In this manner, BSC 8 may route calls between subscriber units 4 and other remote base stations or a conventional telephony system connected to PSTN 10.

Each base station 6 includes a transceiver (not shown) for transmitting signals to, and receiving signals from, subscriber units 4. In particular, for transmissions, each base station 4 may include a number of interconnected components such as one or more transmit modems that produce a serialized stream of data bits organized as frames, one or more summers to combine the data stream produced by the modems, and a transmit power amplifier and an antenna to output a spread-spectrum waveform based on the combined data stream. To facilitate synchronization between the components, the modems introduce one or more parity bits and “entropy” bits within each frame of the data stream. Entropy bits, as used herein, refer to additional bits having values that change relatively frequently, and that are unrelated to the other data bits of the frames. The entropy bits may, for example, be randomly or pseudo-randomly generated.

As described in detail below, the use of an entropy bit helps ensure that “downstream” components, i.e., components within the base station that receive and process the serialized data stream, detect framing misalignment. In particular, the modems introduce an entropy bit within each frame to force the transmitted data to change relatively frequently, and thereby avoid data patterns in which frame misalignment may otherwise go undetected using existing parity error techniques. In this manner, the modems help ensure that the other downstream components converge to the proper framing for the received spread spectrum signals, conserving significant bandwidth previously lost to frame slip. Although illustrated in reference to base stations 6, the use of entropy bits may be incorporated within other components of the system 2 including, for example, subscriber units 4.

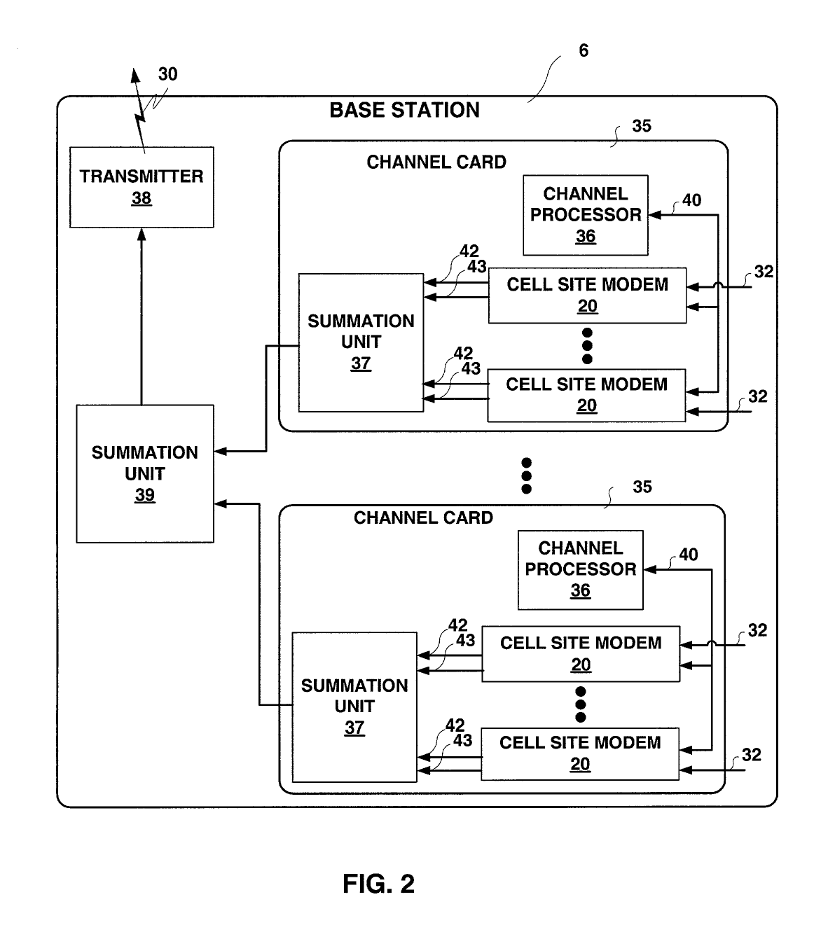

FIG. 2 is a block diagram of a portion of a base station 6 for handling spread spectrum communication for a single channel. Base station 6 includes one or more channel cards 35A -35M. Each channel card 35 includes one or more cell site modems (CSM) 20 that receive voice or data 32, typically as a reverse channel communication from a subscriber unit 4 or data routed from base station controller 8. Each CSM 20 generates a spread spectrum output data stream 42. Each channel card 35 includes a summation unit 37 that combine the output of the CSMs 20 into a resultant serialized stream of data bits. Similarly, summation unit 39 combines the data stream from summation units 37 to a serialized stream of data for communication as a forward channel waveform 30 via transmitter 38. Cell site modems 20 introduce one or more parity bits within each frame of data streams 42 in order to ensure that summation units 37 detect misaligned framing positions be generating parity errors. In this manner, CSMs 20 help ensure that summation units 37 converge to the proper framing for the received spread spectrum data stream 42. In one embodiment, CSMs 20 comprise Wideband Code Division Multiple Access (WCDMA) digital baseband modems for use in a CDMA base station.

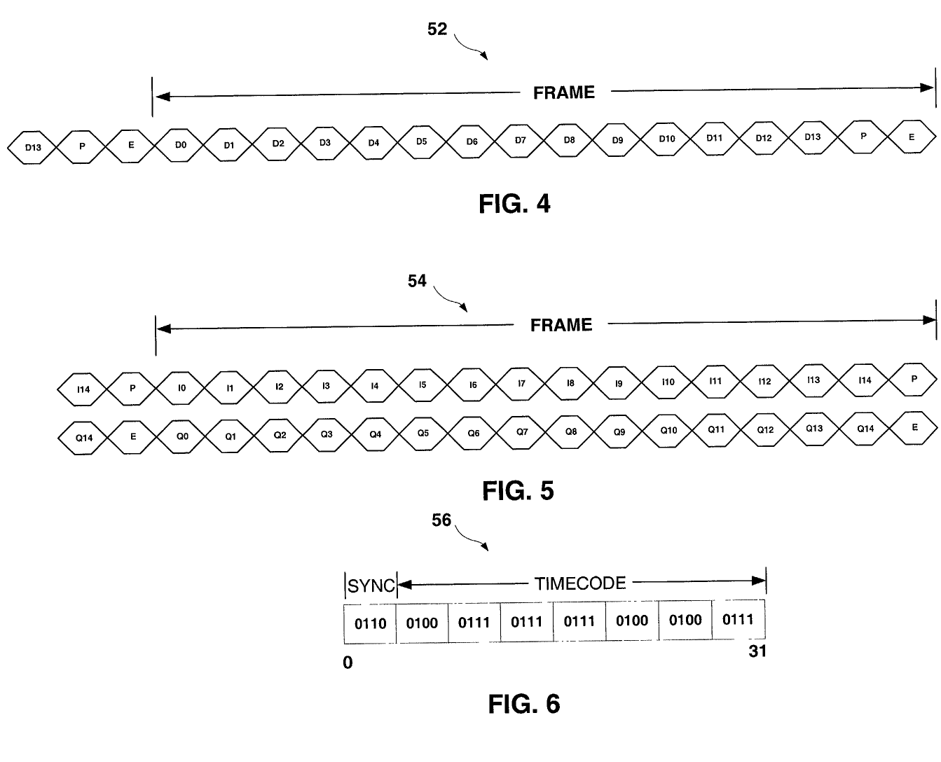

Each CSM 20 operates under the control of a channel processor 36 and supports simultaneous voice or data users. In one embodiment, channel processors 36 may configure CSMs 20 to operate in one of two modes with respect to the frame format of data stream 42. In a first mode, CSMs 20 produces output data streams 42 to carry separate parity bits within each frame of the I and Q complex channels. In this mode, CSMs 20 do not make use of an entropy bit, and may produce synchronization pulses on separate outputs 43 to indicate bit framing. In the second mode, CSMs 20 produce output data streams 42 to include one or more “entropy” bits within each frame, as described in reference to FIG. 4, and do not make use of outputs 43. In this manner, CSMs 20 may be used with a number of different types of transmitters 38 and summation units 37, 39. This operation is described for exemplary purposes only. The principles of the invention may be applied in a modem that only operates in the second mode, i.e., a modem that always introduces one or more entropy bits within data stream 42. In this manner, outputs 43 may be eliminated, thereby reducing the number of interconnections within base station 6.

Without the introduction of the entropy bit by the CSMs 20, summation units 37, and any other downstream components of base stations 6, such as summation unit 39 and transmitter 38, may experience significant periods without detecting parity errors, even when framing is misaligned. This may be particularly noticeable for a data stream representing certain degenerate waveforms, such as unfiltered CDMA signals or a waveform carrying substantially constant data. For example, consider a data stream carrying a constant zero data value in which each data frame carries 15 unsigned data bits, 1 parity bit, and no entropy bits, as illustrated by the following table:

TABLE 1

| FRAMING | DATA BITS | PARITY |
|---|---|---|
| ERROR | [15:1] | BIT[0] |
| 0 BITS | 0000 0000 | 1 |
| | 0000 000 | |
| 1 BIT | 0000 0000 | 0 |
| | 0000 001 | |
| 2 BIT | 0000 0000 | 0 |
| | 0000 010 | |

When properly synchronized (row 1), a summation unit 37 receives a zero value as 15 zero bits followed by a parity bit set to one, assuming parity is defined to have a value of one when an even number of data bits are set to one. A framing error of one bit (row 2), causes the parity bit to be considered as a data bit, and causes data bit [15] of the subsequent frame to be considered as the parity bit. Consequently, without the use of an entropy bit, transmitter 38 will not detect parity errors. Similar, a framing error of two bits (row 3) does not generate a parity error.

Although TABLE 1 illustrates framing 1 bit and 2 bit framing errors, all rotations through a zero value have similar effects in that summation unit 37 does not generate parity errors. Furthermore, this characteristic holds for all constant values, not just zero. In this manner, without the use of an entropy bit, summation unit 37 may otherwise not be able to achieve synchronization with a CSM 20 for substantial periods of time, resulting in wasted bandwidth. Although the use of entropy bits is described in reference to parity schemes, the entropy bits may be used with other error detection schemes using additional parity bits or other redundant information.

Another situation in which parity errors may go undetected is the transmission of sequential pairs of data having values of ±N. For example, consider the sequential transmission of ±1023 as illustrated by TABLE 2:

TABLE 2

| | DATA BITS | PARITY |
|---|---|---|
| VALUE | [15:1] | BIT[0] |
| +1023 | 1111 1111 | 1 |
| | 1100 000 | |
| −1023 | 1000 0000 | 1 |
| | 0011 111 | |

Without the use of an entropy bit, a framing error of a single bit would cause summation unit 37 to receive 1111 1111 1000 0011 followed by 0000 0000 0111 1111, for which summation unit 37 would not generate parity errors. In addition, summation unit 37 does not generate parity errors for framing errors of 3, 5, 7, 9, 11, 13 and 15 bits when receiving data alternating between ±1023. The values of ±1023 are used for exemplary purposes to illustrated a characteristic typical of waveforms carrying values of ±N. Another example involves the values ±64, which do not cause parity errors for framing errors of 0, 1, 2,3,4,5,6,7,9,11, 12 and 15 bits.

A wide variety of permutations generated from these and similar values can also lead to situations in which parity errors may go undetected. For example, consider a waveform the sums any combination of the two values ±1023 and ±64 as illustrated by TABLE 3:

TABLE 3

| | DATA BITS | PARITY |
|---|---|---|
| VALUE | [15:1] | BIT[0] |
| +1087 | 1111 1100 | 0 |
| | 0010 000 | |
| +959 | 1111 1101 | 0 |
| | 1100 000 | |
| −959 | 1000 0010 | 0 |
| | 0011 111 | |
| −1087 | 1000 0011 | 0 |
| | 1101 111 | |

Without the use of an entropy bit, the transmission of any combination of these values does not cause parity errors for framing errors of 0, 1, 3, 5, 7, 9, 11, 13 and 15 bits.

To facilitate synchronization, CSMs 20 introduce one or more entropy bits within each frame in order to ensure that misaligned framing positions return parity errors, even in cases such as those described above involving degenerate waveforms. In particular, the use of an entropy bit ensures the data produced by CSMs 20 experience relatively frequent changes. Consequently, the transmission of certain data, such as the data as illustrated above in TABLES 1, 2, and 3, will generate parity errors when framing error occurs. In one embodiment, CSMs 20 randomly or pseudo-randomly generate an entropy bit for each frame. In another embodiment, CSMs 20 take advantage of the entropy bit to communicate additional information, such as a timing code. Despite the addition of an entropy bit to each frame, there is a savings in system bandwidth with the ability to more rapidly achieve synchronization.

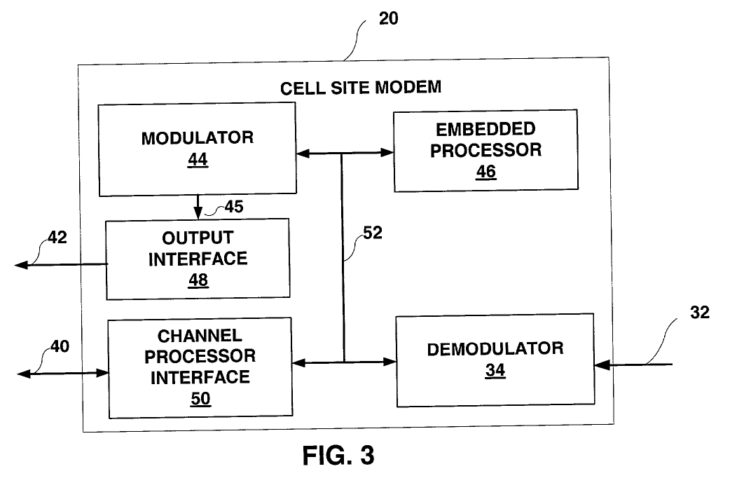

FIG. 3 is a block diagram illustrating an example cell site modem (CSM) 20 according to the invention. CSM 20 includes a demodulator 34 that processes data 32 to produce demodulated data. Conversely, modulator 44 applies a spreading code to outbound serial data, thereby producing outbound spread spectrum data 45. Based on a selected mode of operation, output interface 48 calculates parity and entropy bits for the outbound data 45 to produce output data stream 42 conforming to a particular data frame format. Output interface 48 may include, for example, a random or pseudo-random number generator and parity calculation hardware. Transmitter 38 (FIG. 2) transmits output data stream 42 for communication as a forward channel waveform 30. Internal bus 52 interconnects demodulator 34, modulator 44 and embedded processor 46.

Channel processor interface 50 provides an interface for communication with channel processor 36 (FIG. 2) via control signals 40, and may include control registers or shared memory. In response to control signals 40, embedded processor 46 configures output interface 48. In particular, channel processor 36 selects one of two operating modes for output interface 48 to control the frame format of output data stream 42 as described above.

FIG. 4 is a timing diagram illustrating an example format for a serialized data stream 52 produced by CSM 20 (FIG. 3) that makes use of an entropy bit. Data stream 52 carries serialized data of consecutive frames of sixteen (16) bits. In particular, each frame includes 14 data bits, one parity bit (P) and one entropy bit (E). CSM 20 generates the parity bit based on data bits [D0:D13] and, notably, do not include the entropy bit in the parity calculation. By incorporating an entropy bit within each frame, the data bandwidth has been reduced from 15 bits to 14 bits, but synchronization can be achieved significantly quicker, and may be achieved even in circumstances where synchronization would otherwise not occur.

Consider data stream 52 carrying a constant zero data value, as illustrated by TABLE 4:

TABLE 4

| FRAMING | DATA BITS | | ENTROPY |
|---|---|---|---|
| ERROR | [D0:D13] | PARITY BIT | BIT |
| 0 BITS | 0000 0000 0000 | 1 | 1 |
| | 00 | | |
| 1 BIT | 0000 0000 0000 | 1 | 0 |
| | 01 | | |

If entropy bit (E) is randomly generated, there is a 50% chance that CSM 20 will generate the entropy bit as a one. In this situation, a framing error of one bit (row 2) or greater will generate parity errors. Accordingly, there exists a 50% chance of detecting a parity error for each misaligned frame received. Consequently, there exists only a 25% chance that a parity error would not be generated in two consecutive frames carrying a zero data value. Similarly, there exists only a 12.5% chance that a parity error would not be generated in three consecutive frames of a zero data value.

FIG. 5 is a timing diagram illustrating another example format for a spread spectrum data stream 54 carrying CDMA signals. In particular, data stream 54 carries multiple complex (I&Q) channels. Transmitter 38 receives the two channels in parallel. In this format, CSM 20 generates 30 data bits (I[0:14] and Q[0:14]), one parity bit and one entropy bit, per frame. CSM 20 calculates the parity bit (P) based on all of the data bits (Q and I), and excludes entropy bit (E) from the calculation.

In one embodiment, CSM 20 generates the entropy bit in a random manner. In another embodiment, CSM 20 takes advantage of the entropy bit to communicate additional information, such as a timing code for data stream 54. The timing code typically conforms to a standard format agreed upon by base stations 6 and subscriber units 4. TABLE 5 illustrates an example format in which each value within the timing code is represented by four (4) entropy bits.

TABLE 5

| | ENTROPY BIT |
|---|---|
| DEFINED CODE | PATTERN |
| ZERO | 0100 |
| ONE | 0111 |
| SYNC CODE | 0110 |

Accordingly, FIG. 6 illustrates a bit pattern 56 transmitted by CSM 20 for a current timing code of 0111001. In particular, bit pattern 56 comprises 32 bits, which CSM 20 may transmit using 32 entropy bits of 32 consecutive frames.

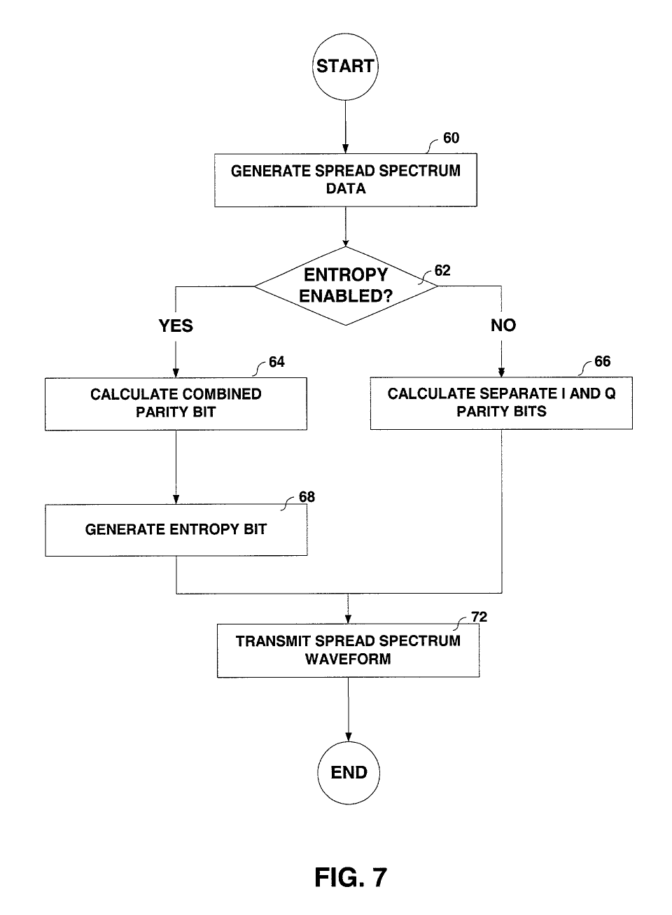

FIG. 7 is a flow chart providing a high-level overview of the operation of a component, such as a modem operating within a CDMA base station, that introduces one or more “entropy” bits to ensure that receiving devices detect misaligned framing positions. Initially, the modem generates spread spectrum data for transmission (60), typically by applying a spreading code to a stream of outbound symbols. Next, the modem controls the frame format for the output data based on a configured operating mode (62). In particular, when configured to operate in a first operating mode (YES branch of 62), the modem produces the output data stream such that each frame includes separate parity bits for the I and Q complex channels (66).

In the second mode, (NO branch of 62) the modem calculates a single parity bit for each frame based on all of the I and Q data bits (64). Next, the modem generates one or more “entropy” bits for each frame of the output data stream, as described in reference to FIG. 4 (68). In one embodiment, the modem randomly or pseudo-randomly generates an entropy bit for each frame. In another embodiment, the modem takes advantage of the entropy bit to communicate additional information, such as a timing code. Finally, a transmitter makes use of the entropy bits to synchronize with the modem, and transmits a forward channel waveform based on the data stream (72). Various embodiments of the invention have been described. For example, a modem for use in component of a spread communication system, such as within a base station or a subscriber unit, has been described that introduces one or more entropy bits within each frame of a transmitted waveform. In this manner, the modem ensures that downstream components detect misaligned framing positions by generating parity errors in situations where the misalignment might otherwise go undetected. In particular, the use of an entropy bit ensures the transmitted data experiences relatively frequent changes. These and other embodiments are within the scope of the following claims.

1. A method comprising:
generating a data stream having data frames, wherein each frame includes at least one bit representing error detection information and at least one entropy bit; and
transmitting a waveform based on the data stream.

2. The method of claim 1, wherein the error detection information comprises parity information.

3. The method of claim 1, wherein generating the data stream comprises calculating the error detection information exclusively of the entropy bit.

4. The method of claim 1, wherein generating the data stream comprises randomly or pseudo-randomly generating the entropy bit.

5. The method of claim 1, wherein generating the data stream comprises encoding a time code within the entropy bits of the data frames.

6. The method of claim 5, wherein encoding a time code within entropy bits of the data frames comprises repeating a 32-bit pattern within entropy bits of 32 consecutive data frames, and further wherein the bit pattern comprises the time code and a synchronization code.

7. The method of claim 6, wherein individual values within the timing code and the synchronization code are represented by four entropy bits in four data frames.

8. The method of claim 1, wherein generating the data stream comprises selectively generating the data stream according to a first frame format or a second frame format based on a configurable setting.

9. The method of claim 8, wherein selectively generating the data stream comprises selectively including the entropy bit within each frame based on the configurable setting.

10. The method of claim 8, wherein each frame includes a set of I and Q data bits for a code division multiple access communication (CDMA) system, and selectively generating the data stream comprises selectively calculating a single parity bit for the I and Q data bits and calculating separate parity bits for the I and Q data bits based on the configurable setting.

11. An apparatus comprising:
a modulator to produce spread spectrum data; and
an output interface coupled to the modulator to generate an outbound data stream from the spread spectrum data, wherein the output interface formats the data stream according to data frames that include at least one bit for error detection and at least one entropy bit.

12. The apparatus of claim 11, further including a transmitter to produce a spread spectrum waveform based on the data stream.

13. The apparatus of claim 11, wherein the error detection information comprises parity information.

14. The apparatus of claim 11, wherein the output interface calculates the error detection information exclusively of the entropy bit.

15. The apparatus of claim 11, wherein the output interface includes a random or pseudo-random number generator to generate the entropy bit.

16. The apparatus of claim 11, wherein the output interface encodes a time code within the entropy bits of the data frames.

17. The apparatus of claim 16, wherein the output interface encodes a 32-bit pattern within entropy bits of consecutive data frames, and further wherein the bit pattern comprises the time code and a synchronization code.

18. The apparatus of claim 11, wherein the output interface selectively formats the data stream according to a first frame format or a second frame format based on a configurable setting.

19. The apparatus of claim 18, wherein the output interface selectively includes the entropy bit within each frame based on the configurable setting.

20. The apparatus of claim 18, wherein the modulator produces I and Q data for a code division multiple access communication (CDMA) system, and further wherein, based on the configurable setting, the output interface selectively calculates a single parity bit for the I and Q data or calculates separate parity bits within each frame for the I and Q data.

21. The apparatus of claim 11, wherein the apparatus comprises a Wideband Code Division Multiple Access (WCDMA) digital baseband modem for use in a CDMA base station.
